(19) United States
(12) Patent Application Publication
(10) Pub. No.: US 2026/0031305 A1
(43) Pub. Date: Jan. 29, 2026

(54) MID-RING EROSION COMPENSATION IN SUBSTRATE PROCESSING SYSTEMS

(71) Applicant: LAM RESEARCH CORPORATION, Fremont, CA (US)

(72) Inventors: Hui Ling HAN, Alameda, CA (US); Seetharaman RAMACHANDRAN, San Jose, CA (US)

(21) Appl. No.: 19/347,266

(22) Filed: Oct. 1, 2025

Related U.S. Application Data
(62) Division of application No. 17/913,008, now Pat. No. 12,444,579.

(51) Int. Cl. H01J 37/32; H01L 21/687

(52) U.S. Cl. CPC H01J 37/32642; H01J 37/32082; H01L 21/68735; H01J 2237/024; H01J 2237/24578; H01J 2237/24585; H01J 2237/334

(57) ABSTRACT

A method includes arranging a first edge ring around a pedestal and a second edge ring around the pedestal under the first edge ring, determining first and second number of hours for which the first and second edge rings are exposed to RF power supplied during substrate processing, determining first and second rates at which the first and second edge rings erode during substrate processing, determining first and second amounts by which to compensate a height of the first edge ring based on the first and second number of hours and the first and second rates, compensating the height of the first edge ring based on erosion of the first and second amounts, and moving the first edge ring relative to the pedestal during substrate processing according to the compensated height, which is equal to a sum of the first and second amounts.

### CROSS-REFERENCE TO RELATED APPLICATIONS

This application is a Divisional of U.S. application Ser. No. 17/913,008 filed Sep. 20, 2022, which is a U.S. National Phase Application under 35 U.S.C. 371 of International Application No. PCT/US2020/024333, filed on Mar. 23, 2020. The entire disclosures of the applications referenced above are incorporated herein by reference.

### FIELD

The present disclosure relates generally to substrate processing systems and more particularly to mid-ring erosion compensation in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A substrate processing system typically includes a plurality of processing chambers (also called process modules) to perform deposition, etching, and other treatments of substrates such as semiconductor wafers. Examples of processes that may be performed on a substrate include, but are not limited to, a plasma enhanced chemical vapor deposition (PECVD), a chemically enhanced plasma vapor deposition (CEPVD), a sputtering physical vapor deposition (PVD), atomic layer deposition (ALD), and plasma enhanced ALD (PEALD). Additional examples of processes that may be performed on a substrate include, but are not limited to, etching (e.g., chemical etching, plasma etching, reactive ion etching, etc.) and cleaning processes.

During processing, a substrate is arranged on a substrate support such as a pedestal, an electrostatic chuck (ESC), and so on in a processing chamber of the substrate processing system. A computer-controlled robot typically transfers substrates from one processing chamber to another in a sequence in which the substrates are to be processed. During deposition, gas mixtures including one or more precursors are introduced into the processing chamber, and plasma is struck to activate chemical reactions. During etching, gas mixtures including etch gases are introduced into the processing chamber, and plasma is struck to activate chemical reactions. The processing chambers are periodically cleaned by supplying a cleaning gas into the processing chamber and striking plasma.

### SUMMARY

A substrate processing system comprises a substrate support assembly to support a semiconductor substrate during processing of the semiconductor substrate in the substrate processing system. A first edge ring is arranged around the substrate support assembly. The first edge ring is movable relative to the substrate support assembly. A second edge ring is arranged around the substrate support assembly and under the first edge ring. A controller is configured to compensate a height of the first edge ring based on erosion of the first and second edge rings.

In another feature, the controller is further configured to determine the erosion of the first and second edge rings based on number of hours for which the first and second edge rings are exposed to RF power supplied during the processing of the semiconductor substrate.

In another feature, the controller is further configured to move the first edge ring relative to the substrate support assembly during the processing of the semiconductor substrate according to the compensated height.

In other features, the controller is further configured to determine a first number of hours for which the first edge ring is exposed to RF power supplied during the processing of the semiconductor substrate. The controller is further configured to determine a first rate at which the first edge ring erodes due to the processing of the semiconductor substrate. The controller is further configured to determine a second number of hours for which the second edge ring is exposed to the RF power. The controller is further configured to determine a second rate at which the second edge ring erodes due to the processing of the semiconductor substrate and due to a movement of the first edge ring. The controller is further configured to compensate the height of the first edge ring based on the first and second number of hours and the first and second rates.

In other features, the controller is further configured to determine a first amount by which to compensate the height of the first edge ring based on the first number of hours and the first rate. The controller is further configured to determine a second amount by which to compensate the height of the first edge ring based on the second number of hours and the second rate. The controller is further configured to compensate the height of the first edge ring based on a sum of the first and second amounts.

In other features, the controller is further configured to determine a shift in height of a tunable edge sheath of plasma used during the processing relative to a preceding first edge ring. The controller is further configured to determine a tuning factor to compensate the height of the first edge ring based on the shift in height of the tunable edge sheath of plasma and based on a last amount used to compensate a height of the preceding first edge ring. The controller is further configured to determine the first amount by which to compensate the height of the first edge ring based on the first number of hours, the first rate, and the tuning factor. The controller is further configured to determine the second amount by which to compensate the height of the first edge ring based on the second number of hours, the second rate, and the tuning factor.

In another feature, the controller is further configured to determine the shift in height of the tunable edge sheath of plasma based on normalized ratios of edge to center etch rates or based on a shift of critical dimension on the semiconductor substrate.

In another feature, the tuning factor is a ratio of the shift in height of the tunable edge sheath of plasma to the last amount used to compensate the height of the preceding first edge ring.

In another feature, the controller is further configured to determine the first rate based on process performance on the semiconductor substrate relative to plasma on time.

In other features, the controller is further configured to determine a correlation between a number of hours for which the second edge ring is exposed to the RF power and an erosion rate of the second edge ring. The controller is further configured to determine the second rate based on the correlation.

In still other features, a method for a substrate processing system comprises arranging a first edge ring around a pedestal in the substrate processing system, arranging a second edge ring around the pedestal under the first edge ring, and compensating a height of the first edge ring based on erosion of the first and second edge rings.

In another feature, the method further comprises determining the erosion of the first and second edge rings based on number of hours for which the first and second edge rings are exposed to RF power supplied during processing of a semiconductor substrate.

In another feature, the method further comprises moving the first edge ring relative to the pedestal during processing of a semiconductor substrate according to the compensated height.

In other features, the method further comprises counting a first number of hours for which the first edge ring is exposed to RF power supplied during processing of a semiconductor substrate. The method further comprises determining a first rate at which the first edge ring erodes due to the processing of the semiconductor substrate. The method further comprises counting a second number of hours for which the second edge ring is exposed to the RF power. The method further comprises determining a second rate at which the second edge ring erodes due to the processing and due to a movement of the first edge ring. The method further comprises compensating the height of the first edge ring based on the first and second number of hours and the first and second rates.

In other features, the method further comprises determining a first amount by which to compensate the height of the first edge ring based on the first number of hours and the first rate. The method further comprises determining a second amount by which to compensate the height of the first edge ring based on the second number of hours and the second rate. The method further comprises compensating the height of the first edge ring based on a sum of the first and second amounts.

In other features, the method further comprises determining a shift in height of a tunable edge sheath of plasma used during the processing relative to a preceding first edge ring. The method further comprises determining a tuning factor to compensate the height of the first edge ring based on the shift in height of the tunable edge sheath of plasma and based on a last amount used to compensate a height of the preceding first edge ring. The method further comprises determining the first amount by which to compensate the height of the first edge ring based on the first number of hours, the first rate, and the tuning factor. The method further comprises determining the second amount by which to compensate the height of the first edge ring based on the second number of hours, the second rate, and the tuning factor.

In another feature, the method further comprises determining the shift in height of the tunable edge sheath of plasma based on normalized ratios of edge to center etch rates or based on a shift of critical dimension on the semiconductor substrate.

In another feature, the method further comprises determining the tuning factor as a ratio of the shift in height of the tunable edge sheath of plasma to the last amount used to compensate the height of the preceding first edge ring.

In another feature, the method further comprises determining the first rate based on process performance on the semiconductor substrate relative to plasma on time.

In other features, the method further comprises determining a correlation between a number of hours for which the second edge ring is exposed to the RF power and an erosion rate of the second edge ring, and determining the second rate based on the correlation.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system including a processing chamber;

FIGS. 2A and 2B show an example of a partial cross-section of a substrate support assembly including a top ring and a mid-ring;

FIG. 3 shows an example of stroke loss using a graph of ratios of edge to center etch rates relative to height of tunable edge sheath (TES) of plasma;

FIG. 4 shows a method for determining a tuning factor to tune height of the top ring according to the present disclosure; and

FIG. 5 shows a method for tuning the height of the top ring using the tuning factor determined according to the method shown in FIG. 4.

In the drawings, reference numbers may be reused to identify similar and/or identical elements.

### DETAILED DESCRIPTION

In processing chambers performing plasma etch processes on semiconductor substrates (typically under vacuum), an edge coupling ring (called a top ring) is arranged around the substrate support assembly to help shape the plasma such that uniform etching of the substrate occurs. After some use, an upper surface of the top ring may exhibit erosion due to the etch processes performed on the substrates. As a result, the plasma may tend to etch a radially outer edge of the substrate at a different rate than radially inner portions of the substrate, and non-uniform etching of the substrate may occur.

To alleviate this problem, lift pins are used to move the top ring up as its top surface gets eroded. The top ring is moved up gradually such that an edge of the top ring is higher relative to a top surface of the substrate. The movement of the top ring changes an edge coupling effect of the plasma relative to the substrate during etching or other substrate treatment. As a result, etch uniformity is improved. The top ring is moved up gradually to maintain an optimal height of the top ring above the substrate support assembly during the lifetime of the top ring.

After some amount of wear due to the erosion, the top ring is replaced with a new top ring. The top ring can be replaced without opening the chamber. Specifically, a robot arm is used to transport the top ring out of the processing chamber and to insert a new top ring into the processing chamber without breaking vacuum.

Under the top ring, a second ring (mid-ring) is arranged surrounding the substrate support assembly. The second ring is called a middle ring or simply mid-ring since there are additional annular structures or rings (e.g., a bottom ring) under the second ring. Unlike the top ring, which is movable, the mid-ring cannot be moved from the processing chamber using the robot arm since it typically has a diameter larger than a port of the processing chamber. An inner edge portion of the mid-ring typically extends under the outer edge of the substrate (called wafer overhang or wafer pocket) and is partially exposed to plasma. As the top ring is moved up during use, the mid-ring begins to erode due to the etch processes performed in the processing chamber. Unlike the top ring, however, which can be replaced without opening the processing chamber, the mid-ring cannot be replaced without opening the chamber.

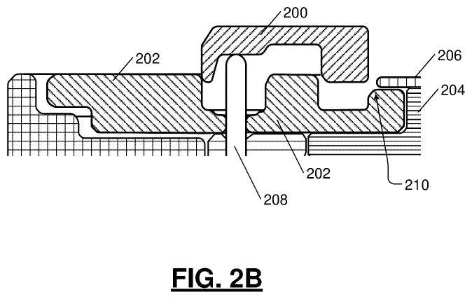

While the top ring is replaced when eroded, the mid-ring continues to erode. The mid-ring erosion is particularly pronounced under the wafer pocket. The mid-ring erosion causes stroke loss (explained below with reference to FIG. 3), which in turn contributes to etch rate non-uniformity across the wafer.

The present disclosure provides a mid-ring erosion compensation method to automatically tune the top ring height to account for top ring and mid-ring erosion and also to ensure full tuning stroke throughout the lifetime of the top ring. Accordingly, the processing chamber need not be opened to replace the mid-ring within mean time between cleaning (MTBC). In other words, the MTBC can be extended. The mid-ring erosion compensation method provides benefits including high edge yield, high MTBC, and low cost of consumables (CoC).

Specifically, the amount of reduction in top ring tuning stroke varies linearly relative to the amount of mid-ring erosion, especially at location under the wafer overhang. The erosion rate of the mid-ring at that location varies linearly relative to the number of RF hours (i.e., total number of hours for which the mid-ring is subjected or exposed to RF power). The present disclosure provides a method to compensate the stroke loss due to the mid-ring erosion so that the processing chamber need not be opened to replace the mid-ring within mean time between cleaning (MTBC).

More specifically, the method tracks the RF hours used on the top and middle edge rings and generates a tuning factor that can be entered via a user interface (UI) based on the process etch rate data. The tuning factor fine tunes the height of the top ring and compensates for mid-ring erosion to ensure full tuning stroke throughout the lifetime of the top ring. These and other features of the present disclosure are described below in detail.

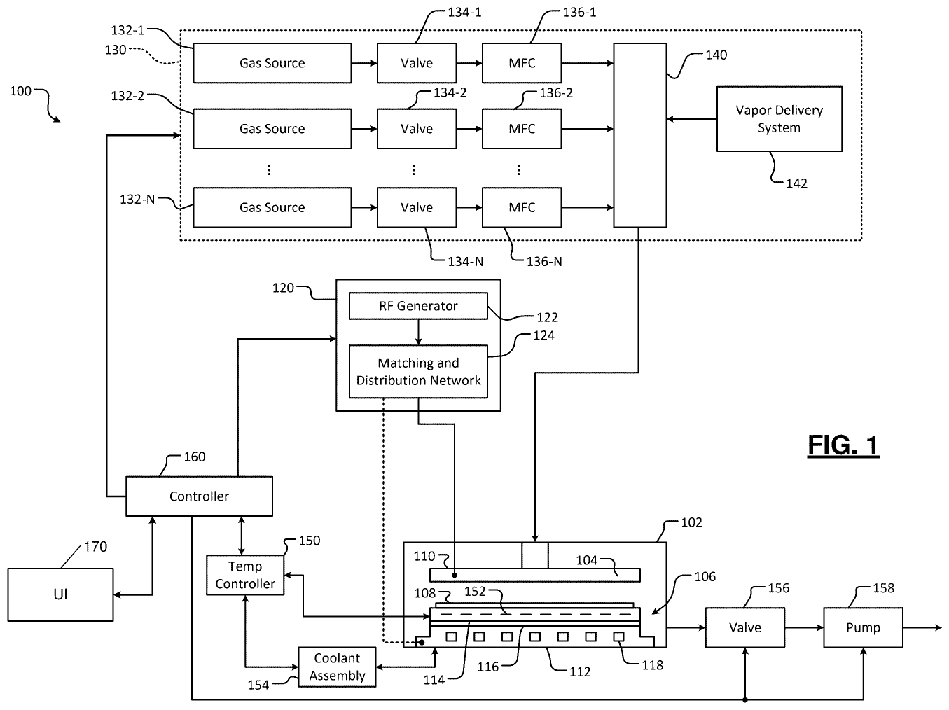

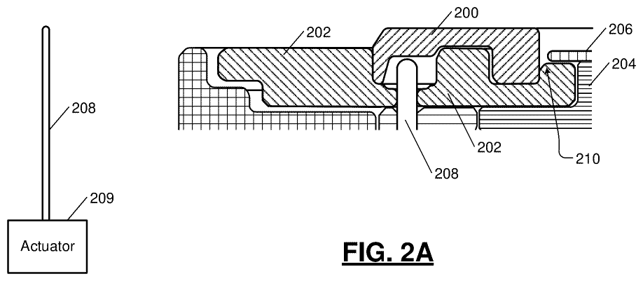

The present disclosure is organized as follows. Initially, an example of a processing chamber is shown and described with reference to FIG. 1 to illustrate where the mid-ring erosion compensation method according to the present disclosure can be used. FIG. 2 shows an example of an arrangement of the top ring and the mid-ring. Thereafter, the mid-ring erosion compensation method is described in detail with reference to FIGS. 3-5.

FIG. 1 shows an example of a substrate processing system 100 comprising a processing chamber 102 configured to generate capacitively coupled plasma. The processing chamber 102 that encloses other components of the substrate processing system 100 and contains RF plasma (if used). The processing chamber 102 comprises an upper electrode 104 and an electrostatic chuck (ESC) 106 or other type of substrate support. During operation, a substrate 108 is arranged on the ESC 106.

For example, the upper electrode 104 may include a gas distribution device 110 such as a showerhead that introduces and distributes process gases. The gas distribution device 110 may include a stem portion including one end connected to a top surface of the processing chamber 102. A base portion of the showerhead is generally cylindrical and extends radially outwardly from an opposite end of the stem portion at a location that is spaced from the top surface of the processing chamber 102. A substrate-facing surface or faceplate of the base portion of the showerhead includes a plurality of holes through which vaporized precursor, process gas, cleaning gas or purge gas flows. Alternately, the upper electrode 104 may include a conducting plate, and the gases may be introduced in another manner.

The ESC 106 comprises a baseplate 112 that acts as a lower electrode. The baseplate 112 supports a heating plate 114, which may correspond to a ceramic multi-zone heating plate. A thermal resistance layer 116 may be arranged between the heating plate 114 and the baseplate 112. The baseplate 112 may include one or more channels 118 for flowing coolant through the baseplate 112.

If plasma is used, an RF generating system (or an RF source) 120 generates and outputs an RF voltage to one of the upper electrode 104 and the lower electrode (e.g., the baseplate 112 of the ESC 106). The other one of the upper electrode 104 and the baseplate 112 may be DC grounded, AC grounded, or floating. For example, the RF generating system 120 may include an RF generator 122 that generates RF power that is fed by a matching and distribution network 124 to the upper electrode 104 or the baseplate 112. In other examples, while not shown, the plasma may be generated inductively or remotely and then supplied to the processing chamber 102.

A gas delivery system 130 includes one or more gas sources 132-1, 132-2, . . . , and 132-N(collectively gas sources 132), where N is an integer greater than zero. The gas sources 132 are connected by valves 134-1, 134-2, . . . , and 134-N(collectively valves 134) and mass flow controllers 136-1, 136-2, . . . , and 136-N(collectively mass flow controllers 136) to a manifold 140. A vapor delivery system 142 supplies vaporized precursor to the manifold 140 or another manifold (not shown) that is connected to the processing chamber 102. An output of the manifold 140 is fed to the processing chamber 102. The gas sources 132 may supply process gases, cleaning gases, and/or purge gases.

A temperature controller 150 may be connected to a plurality of thermal control elements (TCEs) 152 arranged in the heating plate 114. The temperature controller 150 may be used to control the plurality of TCEs 152 to control a temperature of the ESC 106 and the substrate 108. The temperature controller 150 may communicate with a coolant assembly 154 to control coolant flow through the channels 118. For example, the coolant assembly 154 may include a coolant pump, a reservoir, and one or more temperature sensors (not shown). The temperature controller 150 operates the coolant assembly 154 to selectively flow the coolant through the channels 118 to cool the ESC 106. A valve 156 and pump 158 may be used to evacuate reactants from the processing chamber 102.

A system controller 160 controls the components of the substrate processing system 100. A user interface (UI) 170 interfaces with the substrate processing system via the system controller 160.

FIGS. 2A and 2B show an example of a partial cross-section of a substrate support assembly. The example shows a top ring 200 and a mid-ring 202 surrounding a substrate support assembly 204. A substrate 206 is arranged on the substrate support assembly 204. A lift pin 208 and an actuator 209 are used to lift the top ring 200. While only one lift pin 208 is shown in the partial cross-section, it is understood that a plurality of lift pins 208 and respective actuators 209 are used to lift the top ring 200. Examples of actuators 209 include piezoelectric actuators, stepper motors, pneumatic drives, or other suitable actuators. The actuators 209 are controlled by the system controller 160 (shown in FIG. 1).

As the top ring 200 is raised (see FIG. 2B), an inner edge portion 210 of the mid-ring 202 under the outer edge of the substrate 206 (called wafer pocket) begins to erode. The erosion rate of the mid-ring 202 under the wafer pocket (i.e., at location 210) varies linearly relatively to the RF hours (i.e., the total number of hours for which the mid-ring 202 is subjected or exposed to RF power). Further, regardless of the type of material used for the top ring 200 (e.g., quartz, silicon carbide, etc.), the stroke loss of the top ring 200 due to the erosion of the mid-ring 202 varies linearly relative to the mid-ring erosion.

FIG. 3 shows an example of stroke loss using a graph. The graph shows variation of a ratio of normalized edge to center etch rates of a wafer relative to a height of tunable edge sheath (TES) of plasma. For example, for a given etch process, there may be a base height for the top ring 200 and the TES. The TES height increases with the magnitude of the stroke provided by raising the top ring 200 above the base height. For example, the base height for the top ring 200 and the TES may be 2.57 mm. For a 0.5 mm stroke, the TES height may be 3.07 mm; for a 1 mm stroke, the TES height may be 3.57 mm; for a 1.5 mm stroke, the TES height may be 4.07 mm; and for a 2 mm stroke, the TES height may be 4.57 mm.

Each time a new top ring 200 is installed, the continued erosion of the mid-ring 202 causes stroke loss (e.g., 1 mm shown in FIG. 3). That is, raising the top ring 200 by a given distance (e.g., .5 mm) does not change the TES height by the expected amount. The stroke loss increases progressively with each successive top ring 200 until the mid-ring 202 is replaced.

To account for the stroke loss until the mid-ring 202 is replaced, the height of the TES of the plasma can be manipulated by tuning the height of the top ring 200, which in turn helps maintain etch rate uniformity across the wafer. A tuning factor for tuning the height of the top ring 200 is determined (e.g., by the system controller 160 shown in FIG. 1) as follows.

To determine the tuning factor, an amount of shift in the TES height after the top ring replacement is quantified (e.g., “s” mm). A previous height compensation amount (e.g., “a” mm) for the top ring 200 (described below), determined prior to the top ring replacement, is retrieved from memory (e.g., of the system controller 160). The tuning factor is s/a (i.e., s divided by a).

A compensation amount “a” for the installed top ring 200 is determined as follows (e.g., by the system controller 160 shown in FIG. 1). A number of RF hours for the installed top ring 200 is counted using a first counter (e.g., in the system controller 160). The first counter is reset each time the top ring 200 is replaced and a new top ring 200 is installed. The number of RF hours for the installed mid-ring 202 is counted using a second counter (e.g., in the system controller 160). The second counter is not reset each time the top ring 200 is replaced. The second counter is not reset until the mid-ring 202 is replaced.

An erosion rate of the installed top ring 200 is determined (e.g., by the system controller 160 shown in FIG. 1). For example, the erosion rate of the installed top ring 200 can be determined empirically by the system controller 160 based on the number of RF hours for which the installed top ring 200 is subjected or exposed to RF power. Alternatively, the top ring 200 can be transported to an airlock chamber, and a measurement system such as an optical measurement system can be used to scan the top ring 200 and to measure the erosion on the top ring 200 from the data collected by the scanning. By repeating these measurements periodically (e.g., daily), the erosion rate of the top ring 200 can be determined.

An erosion rate of the mid-ring 202 is determined based on the number of RF hours counted by the second counter (e.g., by the system controller 160 shown in FIG. 1). For example, for a given etch process, empirical data may be used to establish a correlation between the number of RF hours and the erosion rate of the mid-ring 202. Using the correlation and the number of RF hours counted by the second counter, the erosion rate of the mid-ring 202 is determined.

The total compensation “a” for the installed top ring 200 is a sum of two terms (determined by the system controller 160 shown in FIG. 1): top ring compensation for the installed top ring 200 and mid-ring compensation for the mid ring 202. The top ring compensation is a product (i.e., multiplication) of the top ring erosion rate, the RF hour count of the first counter, and a third term (1-Tuning Factor) or (1-(s/a′)), where a′ is the last compensation amount for the top ring prior to the top ring replacement, which can be stored in memory in the system controller 160. The mid-ring compensation is a product (i.e., multiplication) of the mid-ring erosion rate, the RF hour count of the second counter, and a third term equal to the Tune Factor (i.e., s/a′).

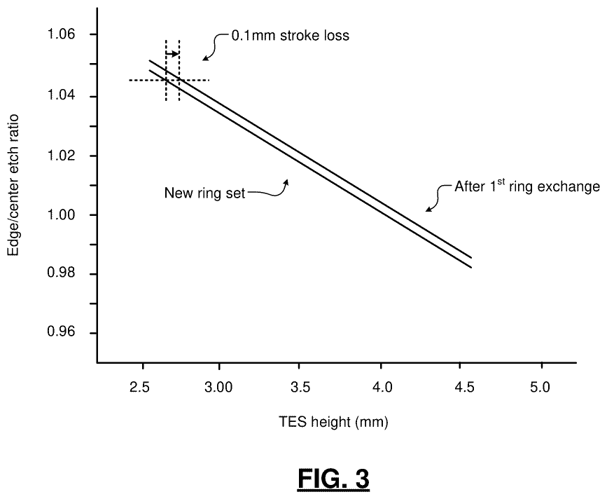

FIG. 4 shows a method 300 for determining the tuning factor with which to tune the height of the top ring 200 according to the present disclosure. For example, the method 300 may be performed by the system controller 160 shown in FIG. 1. At 302, the method 300 determines if the top ring is replaced by a new top ring. If the top ring is replaced, at 304, the method 300 collects etch rate data for an etch process performed on wafers using the new top ring and normalizes ratios of edge to center etch rates for the wafers or, the sensitivity of wafer critical dimension (CD) to the TES height.

At 306, based on the normalized ratios, or the sensitivity of wafer critical dimension (CD) to the TES height, the method 300 quantifies (i.e., measures or determines) the amount of shift(s) in the height of the TES for the new top ring relative to the TES height for the replaced top ring. At 308, the method 308 retrieves a last value of height compensation amount (a′) for the replaced top ring that is stored in memory (e.g., of the system controller 160) prior to replacing the top ring. At 310, the method 300 determines the tuning factor to tune the height of the new top ring as the ratio (s/a′).

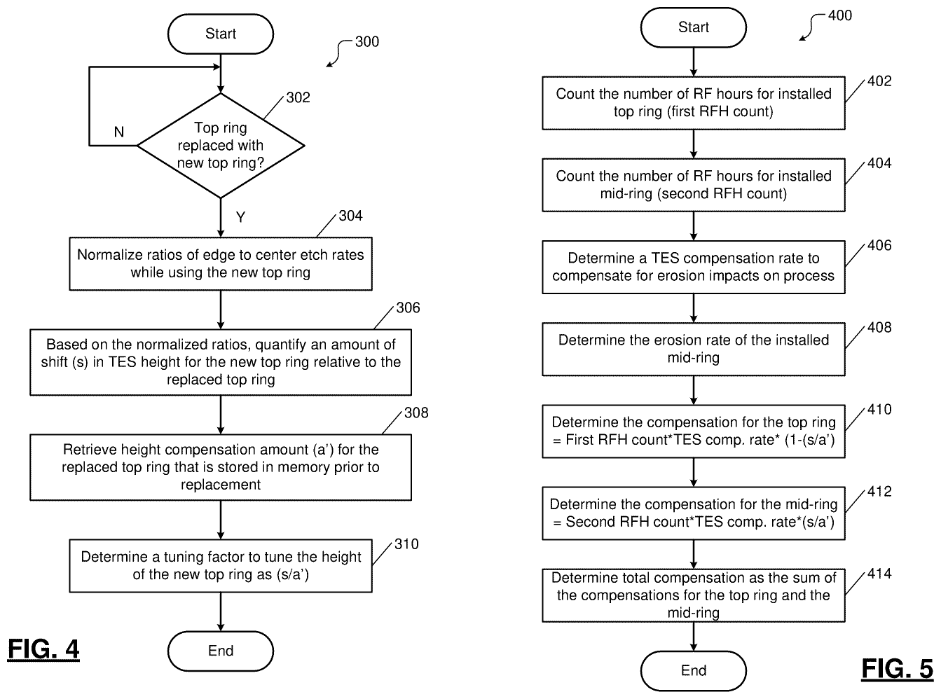

FIG. 5 shows a method 400 for tuning the height of the new top ring using the tuning factor determined according to the method 300. At 402, the method 400 counts the number of RF hours (RFH) for the newly installed top ring (called the first RFH count). At 404, the method 400 counts the number of RF hours for the mid-ring (called the second RFH count). At 406, the method 400 determines a TES compensation rate (mm/RF Hour) to compensate for the erosion impacts on the process (e.g., based on process performance on the semiconductor substrate relative to plasma on time). At 408, the method 400 determines an erosion rate of the mid-ring. At 410, the method 400 determines a compensation amount for the newly installed top ring, which is equal to the product First RFH count*TES compensation rate*(1−(s/a′)), where (s/a′) is determined according to the method 300.

At 412, the method 400 determines the compensation for the mid-ring, which is equal to the product Second RFH count*TES compensation rate*(s/a′), where (s/a′) is determined according to the method 300. At 414, the method 400 determines a total compensation amount for the height of the newly installed top ring, which is the sum of the top ring compensation and the mid-ring compensation. By compensating the height of the top ring by the total compensation amount, the stroke loss due to the erosion of the mid-ring is compensated.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method for a substrate processing system, the method comprising:
arranging a first edge ring around a pedestal in the substrate processing system;
arranging a second edge ring around the pedestal under the first edge ring;
determining a first number of hours for which the first edge ring is exposed to RF power supplied during the processing of a semiconductor substrate;
determining a first rate at which the first edge ring erodes during the processing of the semiconductor substrate;
determining a second number of hours for which the second edge ring is exposed to the RF power;
determining a second rate at which the second edge ring erodes during the processing of the semiconductor substrate and due to a movement of the first edge ring;
determining a first amount by which to compensate a height of the first edge ring based on the first number of hours and the first rate;
determining a second amount by which to compensate the height of the first edge ring based on the second number of hours and the second rate;
compensating the height of the first edge ring based on erosion of the first and second amounts, wherein the compensated height is equal to a sum of the first and second amounts; and
moving the first edge ring relative to the pedestal during the processing of the semiconductor substrate according to the compensated height.

2. The method of claim 1 further comprising:
determining a shift in height of a tunable edge sheath of plasma used during the processing relative to a previously used first edge ring preceding the first edge ring;
determining a tuning factor to compensate the height of the first edge ring based on the shift in height of the tunable edge sheath of plasma and based on a last compensation amount used to compensate a height of the previously used first edge ring preceding the first edge ring;
determining the first amount by which to compensate the height of the first edge ring based on the first number of hours, the first rate, and the tuning factor; and
determining the second amount by which to compensate the height of the first edge ring based on the second number of hours, the second rate, and the tuning factor.

3. The method of claim 2 further comprising determining the shift in height of the tunable edge sheath of plasma based on normalized ratios of edge to center etch rates or based on a shift of critical dimension on the semiconductor substrate.

4. The method of claim 2 further comprising determining the tuning factor as a ratio of the shift in height of the tunable edge sheath of plasma to the last compensation amount used to compensate the height of the previously used first edge ring preceding the first edge ring.

5. The method of claim 1 further comprising determining the first rate based on process performance on the semiconductor substrate relative to plasma on time.

6. The method of claim 1 further comprising:
determining a correlation between a number of hours for which the second edge ring is exposed to the RF power and an erosion rate of the second edge ring; and
determining the second rate based on the correlation.
